(19) United States
(12) Patent Application Publication
(10) Pub. No.: US 2008/0119012 A1
(43) Pub. Date: May 22, 2008

(54) Mold array process for chip encapsulation and substrate strip utilized

(75) Inventor: Wen-Jeng Fan, Hsinchu (TW)

Correspondence Address: TROXELL LAW OFFICE PLLC, SUITE 1404, 5205 LEESBURG PIKE, FALLS CHURCH, VA, 22041, US

(73) Assignee: POWERTECH TECHNOLOGY INC.

(21) Appl. No.: 11/600,925

(22) Filed: Nov. 17, 2006

(51) Int. Cl. H01L 21/00

(52) U.S. Cl. 438/112

(57) ABSTRACT

A MAP (Mold Array Process) for chip encapsulation is disclosed in this invention. First, a substrate strip having a plurality of units is provided. A plurality of chips are disposed on the substrate strip and then an encapsulant is formed made by transfer molding to continuously encapsulate the chips on a plurality of units. Therein, the substrate strip includes at least a first row of units in a one-dimensional array and at least a second row of units in a one-dimensional array and connected with the first row of units in parallel, and the cutting lines between the first row of units are not aligned with those between the second row of units so that the first and second rows of units are disposed in a non-two-dimensional array. Therefore, the mold flows on the cutting lines and on centers of the chips can be balanced merely by means of modifying arrangement of the units without adding obstructions or other extra components to solve conventional encapsulation bubbles generated at sides of the chips.

### FIELD OF THE INVENTION

The present invention relates generally to a chip encapsulating technique, more especially to a MAP (Mold Array Process) for chip encapsulation.

### BACKGROUND OF THE INVENTION

In semiconductor package field, an encapsulant formed with molding method is utilized to protect chip. A plurality of encapsulants may be formed by molds in advance according to the size and quantity of a plurality of units located on a substrate strip to form single-chip encapsulations respectively. Otherwise, another molding method is MAP (Mold Array Process). Firstly, a continuous encapsulant is formed on a substrate strip to encapsulate a plurality of chips and then to cut the encapsulant and the substrate strip along the cutting lines of the substrate strip at the same time so as to obtain cube-shaped MAP type semiconductor packages. Hence, compared to the conventional single-chip molding method, MAP has some merits such as increasing mold compatibility, widely lowering fabricating cost of encapsulant and improving encapsulating efficiency.

Referring to FIG. 1, a well-known MAP semiconductor package 100 mainly comprises a unit 110 of a substrate strip, a chip 120 and an encapsulant 130. There is a difference between the MAP semiconductor package 100 and the conventional single-chip molding semiconductor package which the encapsulant 130 of the MAP semiconductor package 100 has four vertically-cut surfaces at four directions longitudinally aligned with the sides of the unit 110. The chip 120 is disposed on the unit 110 and a plurality of bonding wires 140 formed with wire bonding method are utilized to electrically connect the bonding pads 121 of the chip 120 to the unit 110. The encapsulant 130 is formed on the unit 110 with MAP molding method and then a plurality of external terminals 150 such as solder balls may be disposed under the unit 110. By sawing, the encapsulant 130 has cut surfaces aligned with the unit 110. However, MAP is subject to form encapsulation bubble(s) 131 at one side of chip 120. During MAP as showed in FIG. 2, a plurality of units 110 are disposed in two-dimensional arrays on and integrally connected to a substrate strip and an encapsulant 130 prior to curing according to molding direction 132 is widely encapsulated on the units 110 with molding method, where the chips 120 will block mold flow of the encapsulant 130 so that the mold flow speed above the chips 120 is slower than that along cutting lines between the units 110 and it becomes more and more obvious for the chips 120 disposed in back rows, which the encapsulated area difference between centers (where locate chips 120) and cutting lines between the units 110 becomes more and more bigger resulting in MAP encapsulation bubble 131 problem because the air located around the back rows of chips 120 is late for exhausting.

A semiconductor packaging technique for solving MAP encapsulation bubbles is disclosed in R.O.C. Patent No. I240395 entitled “encapsulating method on an array substrate by molding”. Referring to FIG. 3, a well-known MAP type semiconductor package 200 mainly comprises a unit 210 from a substrate strip, a plurality of obstructions 220, a chip 230 and an encapsulant 240. The obstructions 220 are disposed on peripheries of the unit 210 and the chip 230 is also disposed on center of the unit 210. The bonding pads 231 on the chip 230 are electrically connected to the unit 210 via a plurality of bonding wires 250 formed with wire bonding method. The encapsulant 240 is formed on the unit 210 with MAP molding method to encapsulate the chip 230 and the bonding wires 250. Also a plurality of external terminals 260 such as solder balls are disposed under the unit 210. The obstructions 220 are utilized to slow down mold flow speed flowing at two sides of chips to allow it to match that flowing at center of unit 210 where locates chips 230 for solving MAP encapsulation bubbles problem. However, the obstructions 220 are extra added on the unit 210 that will increase fabricating process and package cost. In addition, since original design has been modified and then the components for assembling semiconductor package are added, the product characteristics of modified semiconductor package 200 need to be reverified.

### SUMMARY OF THE INVENTION

In order to solve the problem mentioned above, the main object of the present invention is to provide a mold array process for chip encapsulation and a substrate strip utilized, which is to apply disposition modification of units in substrate strip for solving the problem on discordant mold flow speeds of encapsulant thereby balancing two mold flow speeds flowing between centers and sides of chip without MAP encapsulation bubbles generated at sides of chip and also the obstructions inside encapsulant utilized in prior technique can be curtailed. Therefore, it is capable of removing MAP encapsulation bubbles without modifying components and structure of original semiconductor package.

One aspect of the present invention provides a MAP for chip encapsulation mainly comprising first providing a substrate strip that includes at least a first row of units in a one-dimensional array and at least a second row of units in another one-dimensional array in parallel. The cutting lines between the first row of units are not aligned with those between the second row of units so that the first and second rows of units are disposed in a non-two-dimensional array. Then, a plurality of chips are disposed on the upper surface of the substrate strip and located in the corresponding first and second rows of units. Next, an encapsulant is formed made by transfer molding on the upper surface of the substrate strip that continuously and substantially encapsulates the chips in the first and second rows of units. Also, a substrate strip utilized during MAP is further disclosed herein.

With regard to the process mentioned above, the cutting lines between the first row of units are aligned with a plurality of center lines of the adjacent second row of units.

With regard to the process mentioned above, the mold flow of the encapsulant along the cutting lines between the first row of units is blocked by some of the chips located on the second row of units to reach mold flow balance.

With regard to the process mentioned above, the first and second rows of units are in same size and in one shape selected from the group consisting of square, rectangle, hexagon and octagon.

With regard to the process mentioned above, a plurality of bonding wires are formed to electrically connect the chips to the substrate strip.

With regard to the process mentioned above, a plurality of external terminals are disposed on the lower surface of the substrate strip.

With regard to the process mentioned above, the external terminals may include a plurality of solder balls.

With regard to the process mentioned above, the substrate strip has at least a mold gate disposed on one side of the substrate strip parallel to and adjacent to the first row of units.

With regard to the process mentioned above, a mold flow direction flowing from the mold gate is approximately perpendicular to the first row of units.

### DESCRIPTION OF THE DRAWINGS

FIG. 1 is a cross-sectional view of a well-known MAP type semiconductor package.

FIG. 2 illustrates the flow speed difference of which an encapsulant flows on array type substrate during well-known MAP.

FIG. 3 is a cross-sectional view of another well-known MAP type semiconductor package.

FIG. 4A to FIG. 4F illustrates a substrate strip during the MAP for semiconductor packages in accordance with the first embodiment of the present invention.

FIG. 5A to FIG. 5C illustrates another substrate strip during the MAP for semiconductor packages in accordance with the second embodiment of the present invention.

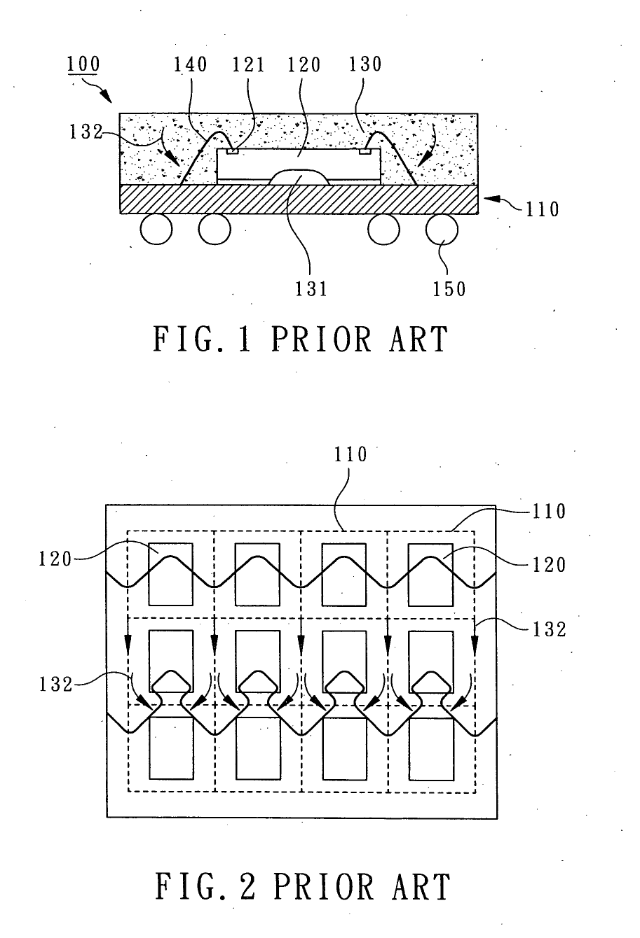

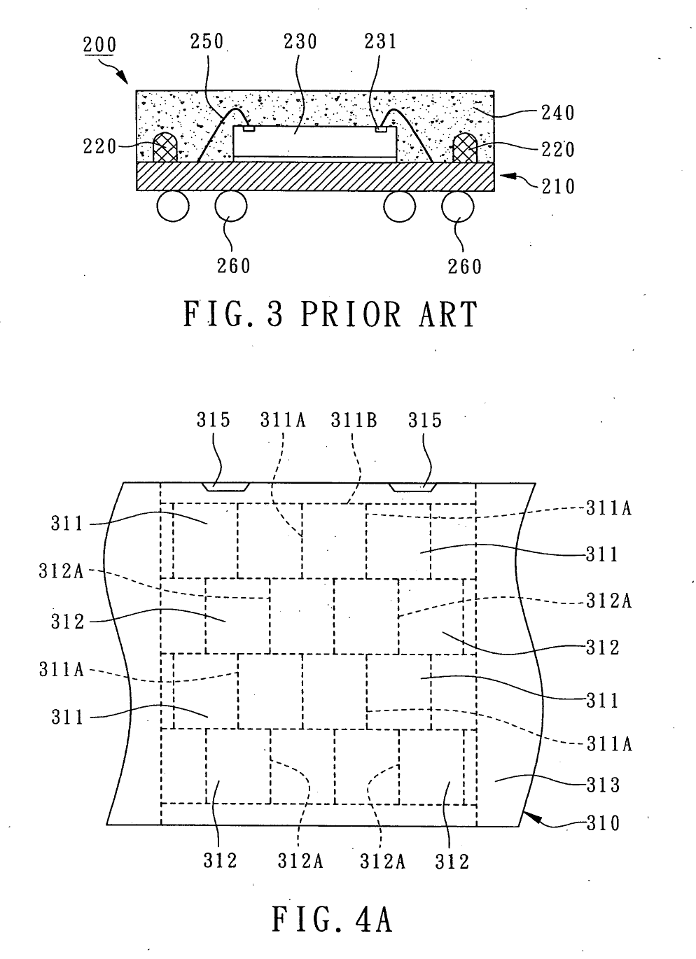

### DETAILED DESCRIPTION OF THE INVENTION

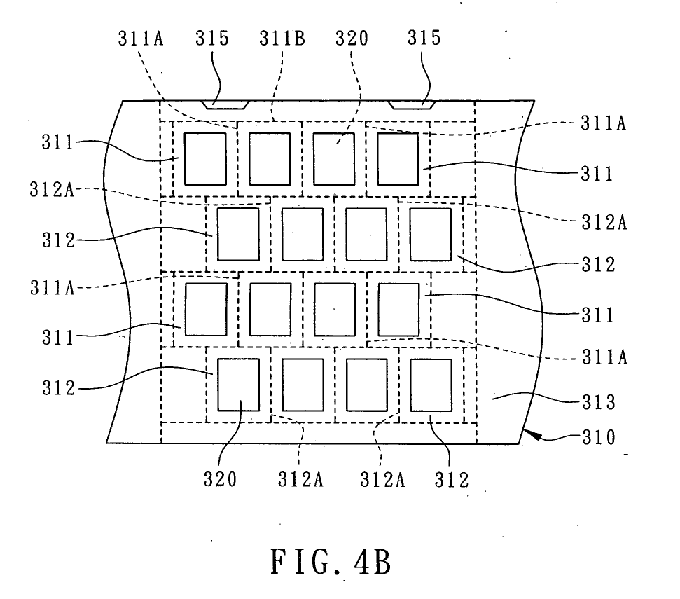

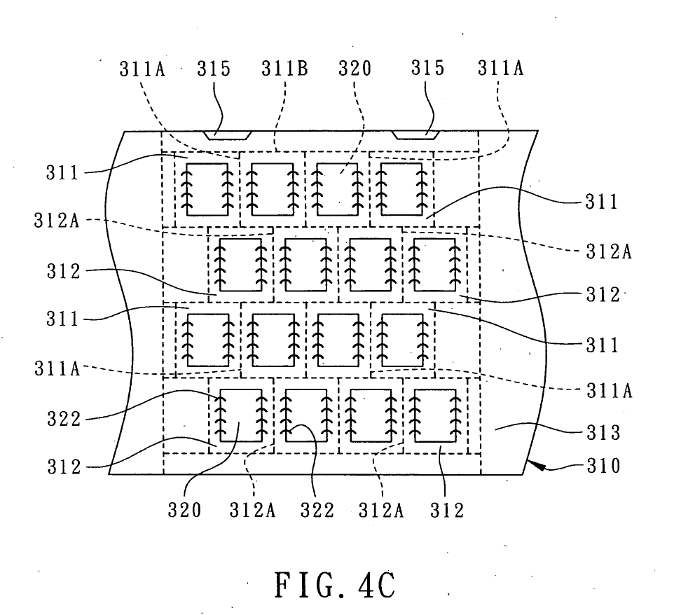

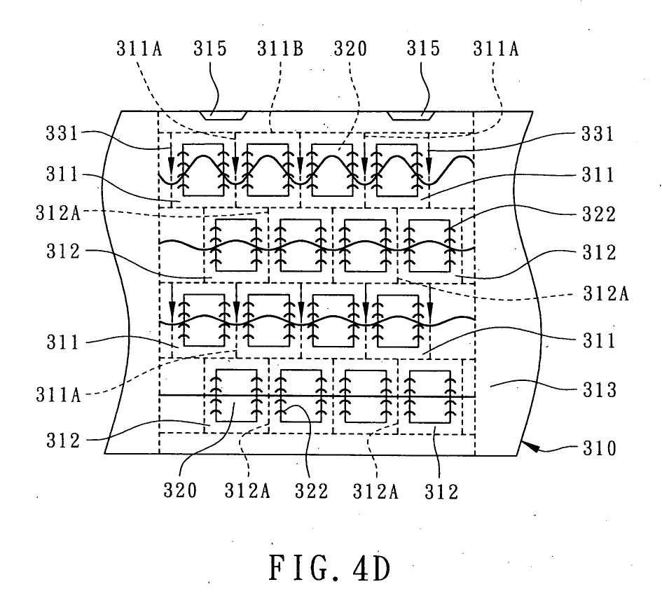

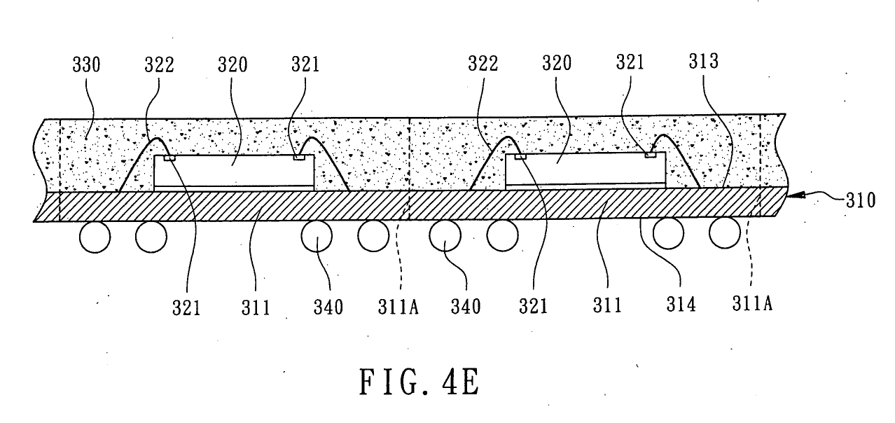

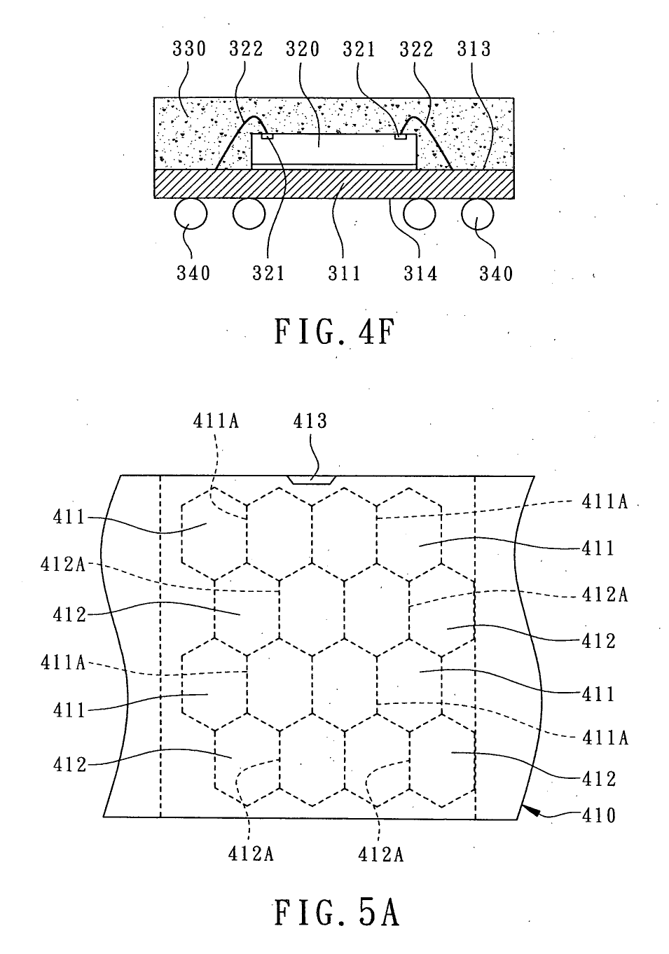

A MAP (Mold Array Process) for chip encapsulation is disclosed in the first embodiment of the present invention as showed in FIG. 4A to FIG. 4F. First referring to FIG. 4A, a substrate strip 310 is provided, which includes at least a first row of units 311 in a one-dimensional array and at least a second row of units 312 in a one-dimensional array and integrally connected with the first row of units 311 in parallel so that they are ranged in staggered fashion. So called “one-dimensional array” is that a plurality of components (units) is ranged in a line with a fixed interval. Moreover, referring to FIG. 4E, the substrate strip 310 has an upper surface 313 for forming an encapsulant 330 and a lower surface 314 for bonding a plurality of external terminals 340 for external surface mounting. In this embodiment, the substrate strip 310 can be a printed circuit board and has wiring pattern(s) for double-sided conductivity therein. Besides, the first and second rows of units 311, 312 may be in same size and in one shape selected from the group consisting of square, rectangle, hexagon and octagon. In this embodiment, both the first and second rows of units 311, 312 have an upper surface approximately in rectangular shape.

Referring now to FIG. 4A, a plurality of cutting lines 311A between the first row of units 311 are not aligned with a plurality of cutting lines 312A between the second row of units 312 so that the first and second rows of units 311 and 312 are disposed in a non-two-dimensional array. So called “non-two-dimensional array” is that arrangement of a plurality of components (units) in longitudinal and transverse is unlike chessboard with alignments in array arrangement.

In this embodiment, the cutting lines 311A between the first row of units 311 are aligned with a plurality of center lines of the adjacent second row of units 312. A plurality of mold gates 315 are disposed on one side of the upper surface 313 of the substrate strip 310 which is parallel to and adjacent to the first row of units 311, for example, it is adjacent to the cutting line 311B at sides of a nearer first row of units 311 as showed in FIG. 4A.

Referring now to FIG. 4B, a plurality of chips 320 are disposed on the upper surface 313 of the substrate strip 310 and located in the corresponding first and second rows of units 311 and 312. Then referring to FIG. 4C and FIG. 4E, a plurality of bonding wires 322 is formed with wire bonding method to electrically connect a plurality of bonding pads 321 on the chips 320 to the substrate strip 310.

Referring now to FIGS. 4D and 4E, an encapsulant 330 is formed made by transfer molding on the upper surface 313 of the substrate strip 310 that continuously and substantially encapsulates the chips 320 on the first and second rows of units 311, 312. Referring to FIG. 4D, in this embodiment, a mold flow direction 331 flowing from the mold gates 315 is approximately perpendicular to the ranging direction of the first row of units 311. The mold flow of the encapsulant 330 along the cutting lines 311A between the first row of units 311 is faster than the one on some of the chips 320 located on the first row of units 311, but is blocked by some of the chips 320 located on the second row of units 312 to become slow thereby balancing mold flows, thus the MAP encapsulation bubbles generated at sides of the back rows of chips 320 can be prevented. Referring now to FIG. 4E, after demolding, the problem on the well-known MAP encapsulation bubbles may be solved without adding the well-known obstructions disposed inside the encapsulant 330.

Finally, referring to FIG. 4F, the encapsulant 330 and the substrate strip 310 may be diced with sawing method to obtain a plurality of semiconductor packages.

Moreover, referring now to FIG. 4E, the MAP for chip encapsulation mentioned above further comprises a step of disposing a plurality of external terminals 340 bonded on the lower surface 314 of the substrate strip 310. The external terminals 340 may include a plurality of solder balls to form BGA semiconductor packages.

Within the semiconductor package mentioned above it is able to balance the mold flow flowing between the sides of the chips with the one on the chips 320 located on the first and second rows of units 311, 312 of the substrate strip 310 during MAP without MAP encapsulation bubbles generated at sides of back rows of chips 320. Accordingly, the problem on MAP encapsulation bubbles can be solved with merely modifying arrangement of original units without adding obstructions inside the encapsulant 330.

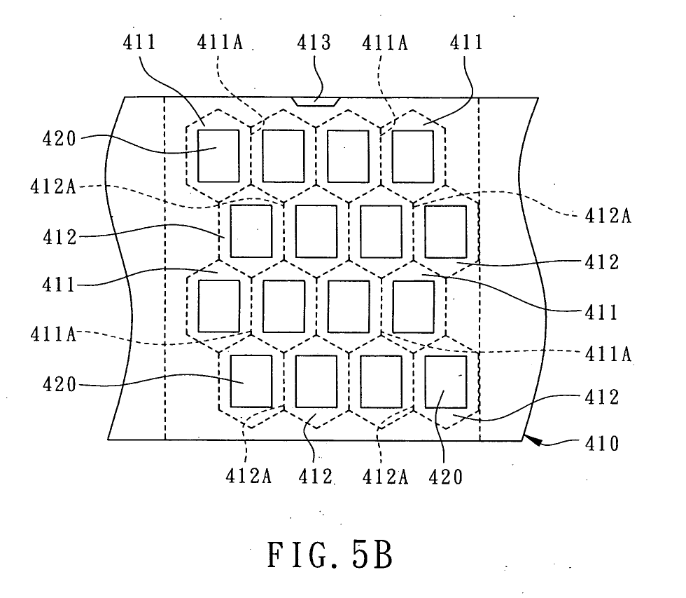

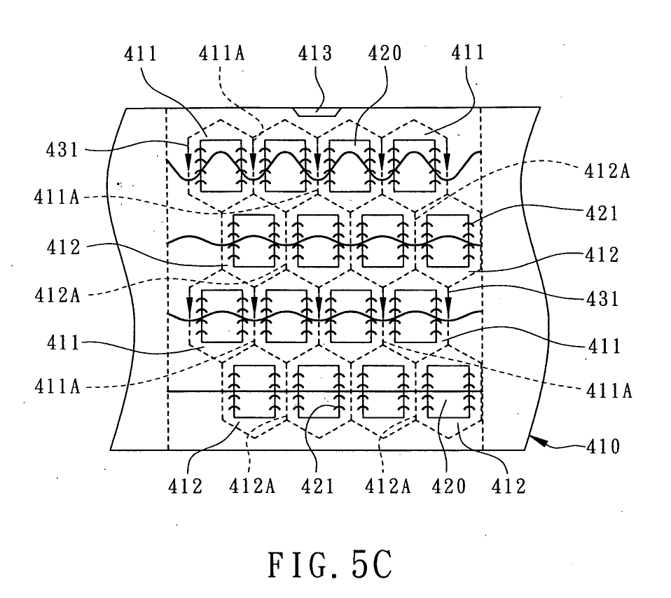

Referring now to FIG. 5A to 5C, another mold array process for chip encapsulation is disclosed in the second embodiment of the present invention. Referring to FIG. 5A, initially a substrate strip 410 is provided, which comprises at least a first row of units 411 in a one-dimensional array and at least a second row of units 412 in a one-dimensional array connected with the first row of units 411 in parallel. The cutting lines 411A between the first row of units 411 are not aligned with those 412A between the second row of units 412 that shows the first and second rows of units 411, 412 are disposed in a non-two-dimensional array. At least a mold gate 413 is disposed on one side of the upper surface of the substrate strip 410 parallel to and adjacent to the first row of units 411. The first and second rows of units 411 and 412 are in same size and in one shape selected from the group consisting of square, rectangle, hexagon and octagon. In this embodiment, the first and second rows of units 411 and 412 are hexagonal. Then referring to FIG. 5B, a plurality of chips 420 are disposed on the upper surface of the substrate strip 410 and located in the corresponding first and second rows of units 411, 412. Finally, referring to FIG. 5C, a plurality of bonding wires 421 are formed to electrically connect the chips 420 to the substrate strip 410 and then an encapsulant (not showed in the drawings) is formed made by transfer molding on the upper surface of the substrate strip 410 that continuously and substantially encapsulates the chips 420 on the first and second rows of units 411, 412. A mold flow direction 431 of the encapsulant flowing from the mold gate 413 is approximately perpendicular to the ranging direction of the first row of units 411. In this embodiment, the mold flow of the encapsulant along the cutting lines 411A between the first row of units 411 is blocked by some of the chips 420 located on the second row of units 412 to reach mold flow balance. The mold flows flowing between sides and centers of the chips 420 can be balanced without extra adding obstructions inside the encapsulant so that there is no MAP encapsulation bubble at sides of chips 420.

While the present invention has been particularly illustrated and described in detail with respect to the preferred embodiments thereof, it will be clearly understood by those skilled in the art that various changed in form and details may be made without departing from the spirit and scope of the present invention.

What is claimed is:

1. A mold array process for chip encapsulation comprising the steps of:
providing a substrate strip including at least a first row of units in a one-dimensional array and at least a second row of units in a one-dimensional array connected with the first row of units in parallel, wherein a plurality of cutting lines between the first row of units are not aligned with those between the second row of units so that the first and second rows of units are disposed in non-two-dimensional array;
disposing a plurality of chips on the upper surface of the substrate strip, the chips being located on the corresponding first and second rows of units; and
forming an encapsulant made by transfer molding, wherein the encapsulant is formed on the substrate strip and continuously encapsulates the chips on the first and second rows of units.

2. The process in accordance with claim 1, wherein the cutting lines between the first row of units are aligned with a plurality of center lines of the adjacent second row of units.

3. The process in accordance with claim 1, wherein the mold flow of the encapsulant along the cutting lines between the first row of units is blocked by some of the chips located on the second row of units to reach mold flow balance.

4. The process in accordance with claim 1, wherein the first and second rows of units are in same size and in one shape selected from the group consisting of square, rectangle, hexagon and octagon.

5. The process in accordance with claim 1, further comprising a step of forming a plurality of bonding wires to electrically connect the chips to the substrate strip.

6. The process in accordance with claim 1, further comprising a step of disposing a plurality of external terminals bonded on a lower surface of the substrate strip.

7. The process in accordance with claim 6, wherein the external terminals include a plurality of solder balls.

8. The process in accordance with claim 1, wherein the substrate strip has at least a mold gate disposed on one side of the substrate strip parallel to and adjacent to the first row of units.

9. The process in accordance with claim 8, wherein a mold flow direction flowing from the mold gate is approximately perpendicular to the first row of units.

10. A substrate strip adopted for mold array process, comprising:
at least a first row of units in a one-dimensional array; and
at least a second row of units in a one-dimensional array connected with the first row of units in parallel, wherein the cutting lines between the first row of units are not aligned with those between the second row of units so that the first and second rows of units are disposed in a non-two-dimensional array.

11. The substrate strip in accordance with claim 10, wherein the cutting lines between the first row of units are aligned with a plurality of center lines of the adjacent second row of units.

12. The substrate strip in accordance with claim 10, wherein the first and second rows of units are in same size and in one shape selected from the group consisting of square, rectangle, hexagon and octagon.

13. The substrate strip in accordance with claim 10, further comprising at least a mold gate disposed on one side of the substrate strip parallel to and adjacent to the first row of units.
